(19) United States
(12) Patent Application Publication
(10) Pub. No.: US 2011/0267773 A1
(43) Pub. Date: Nov. 3, 2011

(54) Holders for tablet computers

(76) Inventor: Scott Macfarlane, Manlius, NY (US)

(21) Appl. No.: 13/080,381

(22) Filed: Apr. 5, 2011

Related U.S. Application Data
(60) Provisional application No. 61/321,006, filed on Apr. 5, 2010.

(51) Int. Cl. H05K 7/00

(52) U.S. Cl. 361/679.55

(57) ABSTRACT

Holders for tablet computers which enable their attachment to vertical and horizontal surfaces, doors, bed frames, kitchen cabinets, the bottom of cabinets and tables, and refrigerators for storage, charging or so that the tablet computer is held in a position for reading while freeing both hands. One holder describes utilizes a modified tablet computer case as the mechanism for securing the tablet computer in the holder.

### PRIORITY

This application claims priority to provisional patent application 61/321,006 filed Apr. 5, 2010.

### BACKGROUND

A new generation of tablet computers has been developed. These include the new iPad® from Apple, the Xoom® from Motorola, Galaxy from Samsung, and the Sahara NetSlate from TabletKiosk, and they are lighter and thinner than previous tablet computers. The Amazon Kindle® and Barnes and Noble Nook® e-readers are types of tablet computers. Even new smartphones like the Thunderbolt from HTC and the iPhone from Apple can be considered small tablet computers. The problem with tablet computers is that they are flat and must typically be held with one or both hands for comfortable use. These tablets are more or less equivalent in form to the display of a desktop or laptop computer, but without the support of the desktop display stand or the laptop base. The interface of many tablets is through the touch screen.

The simplicity of tablet computers allows them to be used in ways that laptop and desktop computers cannot be. A tablet can be used as an e-reader to read a newspaper or magazine at the kitchen table, or to bring a recipe into the kitchen that can be referred to while cooking, or for watching a movie in bed or in the shower, or for surfing the internet while sprawled on a sofa or in an easy chair, or as a personal screen for a conference call. While some simple mounts for tablet computers have been developed, these are modeled after table-top picture frame mounts and desktop display mounts.

For some of the previously mentioned uses, it would be beneficial to have different types of mounts and holders for tablet computers. For example, it would be useful to have a tablet computer holder appropriate for mounting to a kitchen cabinet so a cook could read a recipe displayed on it without having to hold the tablet or place it on the counter where it would get in the way. It would be useful if this mount allowed the angle of the tablet relative to the cabinet to be adjusted. It would be useful having a holder that would support the tablet over a bed or sofa so that a person using it to watch a movie or using it with a keyboard would not have to hold it with his or her hand or support it on his or her knees. It would be useful to have a portable holder or case that would allow the display to be supported at multiple angles and which could optionally also contain a keyboard. It would be useful to have a holder where the tablet could safely be stored and charged while a user is in bed which keeps it close at hand. It would be useful to have a holder that could support a tablet next to a white or chalk board for easy reference. It would be useful to have mounts for tablets for holding a tablet in a readable position for use when in the bathroom.

### SUMMARY

It is a purpose of the present invention to provide useful mount for holding tablet computers when in use and when being stored.

One aspect of the invention is a holder that allows a tablet computer to be stored on the floor, with a protective enclosure for the tablet and a wide flange that extends at a right angle to either side of the enclosure so that the tablet is held vertical for easy access. In one embodiment the holder is a charging dock.

One aspect of the invention is a charging dock for a tablet computer incorporating a bracket adapted for attachment to and suspension from a standard metal bed frame. The bracket hooks snugly over the top of the angle iron and the holder hangs vertically from it. An optional screw can make the attachment more secure. In one embodiment, the bracket is adapted to hold the tablet holder horizontally under the bed, the bracket either hooking over the top of the vertical portion of the bed frame's angle iron or over the horizontal part of the angle iron.

One aspect of the present invention is a holder for a tablet computer having a bracket for mounting the holder to the bottom of a horizontal planar surface with the tablet held vertically.

One aspect of the invention is a spring-loaded tablet holder where a part of the holder grips the edge of the tablet computer. In one embodiment, the spring-loaded holder is pivotably attached to an arm which is pivotably attached to a mounting bracket, enabling the tablet computer to be swung horizontally away from the mount and pivoted horizontally relative to the arm. In one embodiment, the mounting bracket is adapted to mount to a vertical planar surface. In one embodiment, the mounting bracket is adapted to mount to the underside of a horizontal planar surface and allow the arm to swing horizontally. In one embodiment, the holder is a holster-type holder and the holster-type holder is attached to the arm by a gimbal which allows the angle of the tablet to be changed both vertically and horizontally.

One aspect of the invention is a slot-type holder for a tablet computer pivotably attached to a mounting bracket. In one embodiment, the mounting bracket is adapted to mount to a vertical planar surface. In one embodiment, the mounting bracket is adapted to mount to the bottom edge of a relatively thin, rectangular and vertically oriented object, such as a cabinet door.

One aspect of the invention is a slot-type holder for a tablet computer mounted to a telescoping support adapted to be mounted to the underside of a horizontal planar object such as a kitchen cabinet. The holder can be extended out beyond the underside of the object to which it is mounted or slid under the object when not in use. In one embodiment, the holder is a charging dock.

One aspect of the present invention is a slot-type holder for a tablet computer incorporating a mounting bracket for mounting to a refrigerator or other door. In one embodiment, the bracket hooks completely over the top edge of the door and is secured by pressure applied by screws. In one embodiment, the bracket is a flange extending over the top of the door and secured to the door by magnets on the back of the holder and the bracket. In one embodiment the holder is secured to the refrigerator door solely by magnets or adhesive strips. In one embodiment the holder is a charging dock.

One aspect of the invention is a holder for tablet computers into which a tablet can be snapped and from which it can be pulled.

One aspect of the invention is a holder for a tablet computer incorporating a swing arm, a mounting bracket and a holster-type holder for a tablet computer. In one embodiment, the swing arm is a spring balanced spring arm. In one embodiment, the swing arm is a friction swing arm. In one embodiment, the holder incorporates a pivot mounting bracket such as those used to secure swing arm lamps to tables. In one embodiment, the holder incorporates a pivot mounting bracket with a J-shaped pivot rod adapted for mounting to a standard angle-iron bed frame so that the swing arm can be folded and stored under the bed. In one embodiment, the holder incorporates speakers.

One aspect of the invention is a holder that can hold onto the top edge of a tablet computer and suspend it from the bottom of a horizontal surface, the holder comprising a slot with a longitudinal element which the back side of the tablet will press against and pivot around and a high friction element against which the front side of the tablet will press.

One aspect of the present invention is a system for holding a tablet computer comprising a case with a slot or recess formed into it or a pocket attached to it and a holder comprising a mounting bracket attached to a support element or an insertion element, where the insertion element is inserted into the slot, recess or pocket to support the tablet computer in the case. In one embodiment there are two slots, recesses or pockets situated orthogonal to one another so that the case can be suspended from the insertion element in either the portrait or landscape orientation.

In some embodiments, the holder is a charging dock. In some embodiments, the holder incorporates speakers and/or a light.

### BRIEF DESCRIPTION OF THE DRAWINGS

FIG. 1 is a perspective view of a floor holder for a tablet computer and is a charging dock.

FIG. 2 is a perspective view of a holder for a tablet computer that mounts to a bed frame and holds the tablet vertically and is a charging dock.

FIG. 3A is a perspective view of a holder for a tablet computer that mounts to a bed frame and holds the tablet horizontally and is a charging dock.

FIG. 3B is a partial perspective view of an alternate bracket for attaching a holder for a tablet computer to a bed frame so that the tablet is held horizontally.

FIG. 4A is a perspective view of a holder for a tablet computer that can be attached to a vertical surface.

FIG. 4B is a perspective view of a bracket for attaching a holder for a tablet computer to a horizontal surface.

FIG. 5A is a perspective view of a holder for a tablet computer that can be attached to a vertical surface.

FIG. 5B is a perspective view of a bracket for attaching a holder for a tablet computer to the bottom edge of a thin vertical object such as a cabinet door.

FIG. 6 is a perspective view of a retractable holder for a tablet computer that can be mounted under a kitchen cabinet or other horizontal surface.

FIG. 7 is a perspective view of a holder for a tablet computer that can be mounted on a refrigerator door.

FIG. 8 is a perspective view of a holder for a tablet computer that can be mounted along the bottom of a cabinet door.

FIG. 9 is a perspective view of a holder for a tablet computer that is a charging dock which can be mounted over the top of a door.

FIG. 10 is a perspective view of a holder for a tablet computer into which the tablet is pushed.

FIG. 11A is a perspective view of a swing arm holder for a tablet computer that can be attached to a bed.

FIG. 11B is a perspective view of a swing arm holder for a tablet computer in its storage position.

FIG. 12 is a perspective view of a holder for a tablet computer that can be attached to the bottom of a horizontal surface and from which the tablet computer hangs.

FIG. 13 is a perspective view of a pivoting holder for a tablet computer that can be attached to the bottom of a horizontal surface and from which the tablet computer hangs.

FIG. 14A is a perspective view of a holder for a tablet computer that can be attached horizontally to a vertical planar surface and from which the tablet computer hangs.

FIG. 14B is a side view of the holder of FIG. 14A holding a tablet computer.

FIG. 15 is a perspective view of a fold down holder for tablet computers that can be attached to a vertical surface.

FIG. 16 is a perspective view of a tablet computer holder and dock for suspending the tablet.

FIG. 17A is a perspective view of a holder for a tablet computer that works in conjunction with a specially adapted tablet computer case or housing.

FIG. 17B is a plan view of the back side of a tablet computer case adapted to be used with the holder shown in FIG. 17A.

### DETAILED DESCRIPTION OF THE DRAWINGS

Tablet computer owners use tablets in bed, and after use need a storage recharging dock that allows the tablets to be stored for the night out of the way while recharging, but within easy reach from bed for easy access in the morning. Their size makes tabletop recharging docks such as those used for cell phones and smart phones inconvenient.

One embodiment of the present invention is the floor storage recharging dock 600 shown in perspective in FIG. 1. The dock comprises an enclosure 601 (a tube with a rectangular cross-section, with the long side much longer than the narrow side, slightly bigger than the cross-section of the tablet computer or computers for which it is designed) supported in a vertical orientation by a flange 602 extending from the opposing wide sides of the enclosure 601 (the flange can be a planar rectangular element attached to the end of and perpendicular to the rectangular tube that forms the enclosure 601 which is wider than the cross-section of the tube and also encloses the end). The enclosure 601 encloses a slot 611 that is sized to fit a tablet computer, preferably sufficiently closely that the tablet will not have much room to move within the enclosure 601. The purpose of the flange 602 is to provide a more stable support for the enclosure 601 and prevent the dock 600 from tipping over. The flange 602 extends perpendicular to the edge of a wide side 610 of the enclosure 601 at its base. Since tablets come in different sizes with docking/charging ports being different in form and positioned in different positions, dock 600 is preferably customized to fit a particular brand of tablet. Enclosure 601 is dimensioned to fit a tablet computer oriented vertically on one edge, and can be sized to the tablet or made large enough to fit the tablet when enclosed in a case. It is open at a top end 606 and closed at the opposite end from which the flange extends. In the base of the enclosure is an electrical connector (not shown) positioned for connection to the tablet's charging port when the tablet is inserted into the enclosure 601. The electrical connector will match the type of tablet for which the dock 600 is intended, and is connected by a wire 609 to a plug-in transformer 608 optionally. Alternately, the transformer can be built into the dock 600, such as on the support flange 602 and connected to a power outlet via a standard electrical cord. Alternately, an induction type charger can be built into a wide side 610 of the enclosure, eliminating the need for an electrical connector in the base of the enclosure 601. The enclosure 601 must have sufficient depth so that the tablet will not fall out but preferably will be deep enough that most of the tablet is covered to protect it while it is charging from inadvertent kicks and dust. If the enclosure 601 is deep, then in order to be able to pull the tablet out of the dock 600, a pair of opposing finger tip-sized notches 605 can optionally be formed in the wide sides of the top end 606 of the enclosure so that a person can grip the tablet with thumb and a finger. The enclosure 601 can be designed to accommodate the tablet in portrait or landscape orientation. A lever accessible from outside the enclosure which when pushed lifts the tablet therein can also be incorporated into the holder. The flange 602 can incorporate holes to allow it to be, screwed to the floor, or could have adhesive on its underside, or it can be weighted to provide more stability for the dock 600, such as by incorporating into or making the flange 602 and/or bottom end from a mass weighing one or more times the weight of the tablet computer it will be used with (preferably at least several times more, such as 4 or 5 or even 10 pounds).

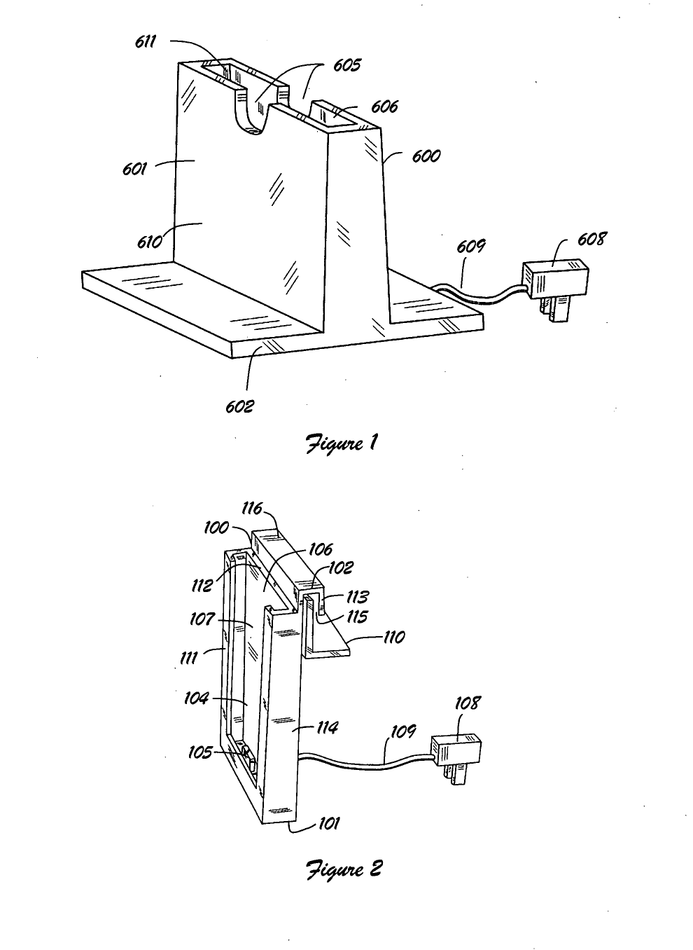

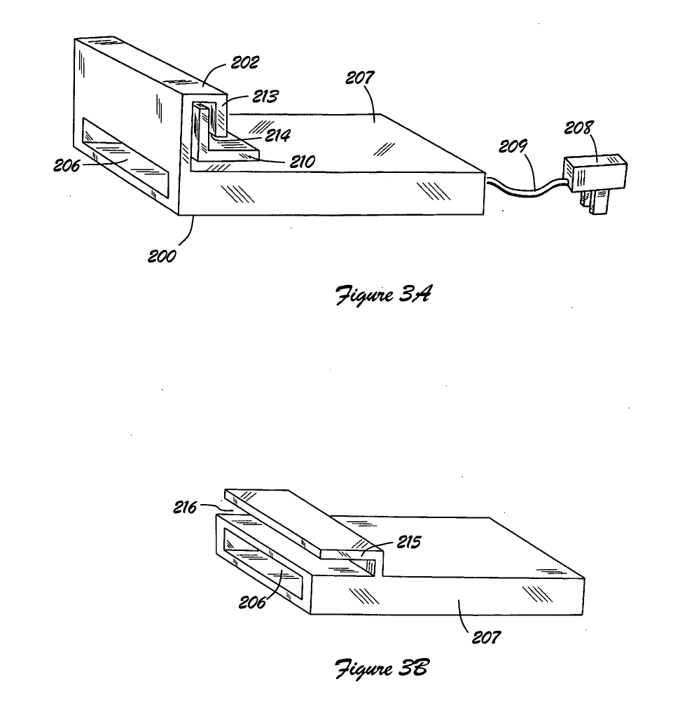

One embodiment of the present invention is the charging dock 100 shown in perspective in FIG. 2, which is adapted to hang vertically from the angle iron rail of a standard metal bed frame (a portion is shown as 110). Dock 100 comprises a holster-type holder 101 which is designed to allow a tablet computer to be inserted edge first into it and is an enlarged version of the holster holders available for many cell phones. It has a back 104, three narrow sides 114 along three edges of the back 104 with inward extending flanges 111 at their outer edge (away from the back) adapted to restrain the tablet so it stays in the dock 100. The holder 101 is an enclosure with a mostly open front side with the aforementioned flanges on three sides forming an open-ended enclosure 107 sized and shaped to fit a tablet computer (preferably a specific type or brand), having an open top end 106 into which the tablet can be inserted. Alternatively, the front side can be solid. Dock 100 optionally comprises a charging connector 105 in its bottom side which mates with the appropriate port of the tablet when it is properly inserted into the holder 101, and is attached electrically by electrical cord 109 to a plug-in transformer 108. In one embodiment the charging connector 105 is replaced by an induction charger incorporated into the back 104.

At the upper end of the back 104 is an L-shaped bracket 102 adapted to hook over the upward extending part of the bed frame's angle iron 110. The bracket 102 comprises two legs 116 and 113 perpendicular to each other and joined along one edge. The bracket 102 is attached along the edge of a first leg 116 to the upper edge of the back 104, the attached first leg 116 extending perpendicular from the back 104, with the second leg 113 then extending downwards to create a slot 115 for the bed frame angle iron 110 to fit into, preferably snugly, and can have a layer of foam rubber or other material to improve the grip of the bracket 102 on the frame 110 and to protect the frame 110 from damage and prevent the holder from rattling. The downward extending leg 113 of the bracket 102 is preferably thin and planar so that it more easily slips between the frame 110 and a box spring placed into the frame.

Other bracket designs are possible. In one embodiment, the bracket is removed and the dock 100 is held to the bed frame by magnets attached to the top of the back 104. In this embodiment the back optionally has a small flange at its top which extends over the thin part of the angle iron 110 to prevent it from sliding downwards, but which does not interfere with a box spring in the frame. In another embodiment without the bracket, holes are formed in the back 104 of the dock 100 to allow it to be mounted to a vertical surface using a fastener such as a screw. In another embodiment, the bracket 102 is replaced by a flange perpendicular to the back 104. The flange has holes in it to allow the flange to be mounted to a horizontal surface, either to the bottom or to the top of the horizontal surface, with the holster holder 101 vertically oriented.

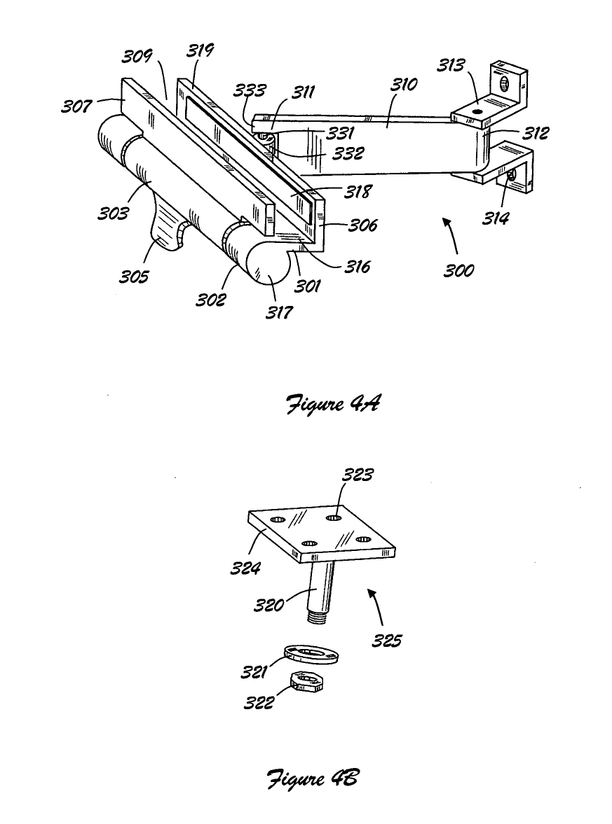

One embodiment of the present invention is a charging dock 200 for a tablet computer, shown in perspective in FIG. 3A, which can be suspended from a bed frame. In this embodiment, the tablet is horizontal to the ground when inserted into the dock 200. Dock 200 comprises a hollow enclosure 207 having an open end 206 into which a tablet computer can be inserted edge-first. At the end of the enclosure 207 opposite the opening is an electrical connector (not shown) designed to mate with an electrical port on the tablet when the tablet is fully inserted (optionally the connector can be replaced by an induction charger incorporated into the appropriate wall of the enclosure 207), with the connector connected electrically to a transformer 208 by an electrical wire 209. The transformer can be incorporated into the dock 200 or at the end of the wire 209 as shown. The length of the enclosure 207 may be slightly shorter than the tablet to expose an edge that can be gripped to extract the tablet, or notches, such as notches 605 in the enclosure 601 in the embodiment shown in FIG. 1, can be made in the enclosure, either in the wide sides or narrow sides. The enclosure 207 can be a solid enclosure except at the open end 206 or can have one or more open sides such as those in the embodiment shown in FIG. 1.

Dock 200 comprises an elongate hook-shaped bracket 202 attached perpendicularly adjacent to the open end 206 (or optionally attached at a different angle) of the enclosure 207 so that the bracket 202 hooks up and over the upwardly extending edge of the bed frame angle iron 210 to support the enclosure 207 so that the enclosure 207 extends horizontally below the frame 210 element and under the bed (not shown). The bracket 202 has a downward extending element 213 forming a slot 214 just large enough to fit the upward extending flat part of the angle iron, and it extends far enough down to securely hold the enclosure 207 in a substantially horizontal position (the bracket must be relatively strong because a considerable force may be applied to the downward element 213 and the bracket overall by the weight of the tablet computer in the enclosure). The distance between the end of the downward extending element 213 and the enclosure 207 must be big enough that the angle iron 210 can be inserted into the space formed by the hook.

In another embodiment, a cutaway portion of which is shown in FIG. 3B, the bracket 215 replaces the bracket 202 shown in FIG. 3, and forms a slot 216 with the enclosure 207 into which the horizontally extending leg of the bed frame angle iron 210 can slide. The dock 200 is suspended horizontally under the bed frame with its open end 206 roughly flush with the upward extending leg of the angle iron. A small catch can be incorporated into the front edge of the dock adjacent to the open end and in the upward facing side that will catch on the upward extending leg of the angle iron adjacent to the angle and help the dock resist sliding off the frame.

Other types of bed frames are made, and these embodiments can be adapted so that vertically and horizontally oriented charging docks can be attached to them. For example, if the frame is wooden and thicker than the steel angle iron above, the slot formed by the bracket can be larger. Also, the bracket can have holes for screws securing the dock to the bed frame.

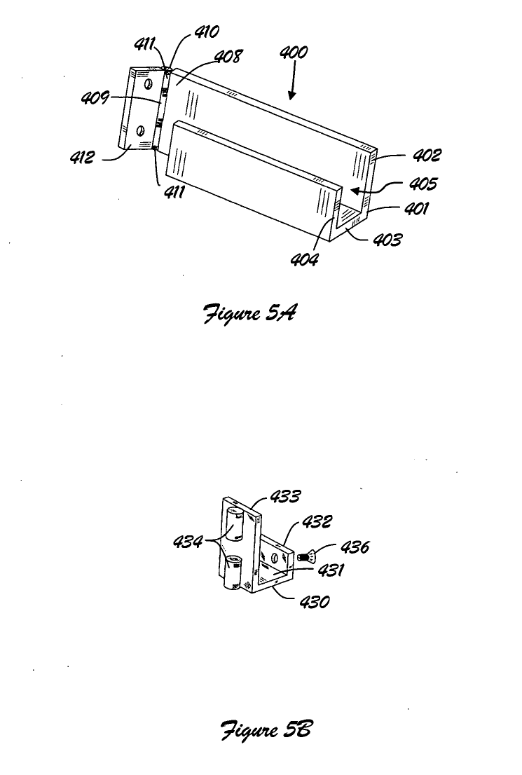

Since tablets are used for reading, holders that will support the tablet at an appropriate angle are useful. For example, it would be useful to have a holder mounted in bathrooms at an appropriate height for holding the tablet for reading while sitting on the toilet or in the kitchen for holding a tablet on which is displayed a recipe. For some such holders it may be advantageous for the holder to swing or slide out of the way or out of sight when not in use. FIG. 4A is a perspective view of a slot-type holder 300. A holster-type holder for a tablet is an enclosure into which the tablet can be inserted, like a holster for a pistol or a cell phone in a phone holster. A slot-type holder comprises front and back generally planar elements which are each connected along one edge to a base element which results in the formation of a space or slot between the front and back elements. One edge of a tablet is inserted into the slot with the edge parallel to the base element, and the back element is generally designed to support the back of the tablet (the non-display side) while the front element is designed to prevent the tablet, whose center of mass is outside the slot, from pivoting over the back element and falling out of the holder; the front element catches its edge within the slot and restricts its movement as the tablet tries to pivot around the upper edge of the back element. The back element is generally much shorter than the vertical dimension of the tablet when the tablet is in the slot and may be angled away from the base (e.g., at a greater than 90 degree angle to the base) so that the tablet's display will be angled slightly up when in the slot. The front element must only be high enough (as measured away from the base) to catch the edge of the tablet and prevent it from pivoting around the back edge, a height generally less than that of the back element, and should not obscure either the display or any buttons beneath the display (notches can be formed in the front element to provide access to buttons if necessary). The back and front elements are spaced by the base further apart than the thickness of the tablet for which the holder is designed. The back and front elements can be fixed, with the tablet being retained in the slot by gravity. Alternatively, either the front or back element, or both, can be spring loaded to apply a force to the tablet to help hold it in the slot. The front and back elements can optionally have layers whose purpose is, for example, to hold the tablet better (for instance by increasing the friction between the element and the tablet) or protect the tablet from abrasion by the holder elements. In some embodiments, the slot can be sized and constructed to hold the edge of a tablet in a vertical or near vertical orientation. In these embodiments, the slot actively secures the tablet in position and prevents it from falling out.

Slot-type holder 300 comprises a slot holder 301 with a slot 309 large enough to fit a tablet and wide enough to provide a solid support for the tablet edge that is inserted (it can be smaller than that edge's longest dimension, but should not be so small that a slight movement of the tablet in either direction along the slot will cause it to fall out). A slot or channel 309 is formed between back element or support 306 and front element 307 which are preferably planar and roughly parallel or slightly angled apart at their free top edge and spaced far enough apart to fit a tablet computer edge-wise. The back and front elements can be angled from the vertical so that the tablet's display will also be at an angle to the vertical (or they can be spaced far enough apart that the tablet will naturally lean). In the embodiment shown, the slot holder 301 has a spring mechanism similar to spring-loaded hinges. Back support 306 is part of an L-shaped back element 319 comprising the planar back support 306, a planar bottom element 316 and a hinge barrel 302. The bottom 316 is attached to the back 306 at one edge at a roughly parallel angle and is attached to the hinge barrel 302 on the opposite edge. The hinge barrel 302 comprises two axially aligned hollow cylinders separated by a space into which the middle hinge barrel 303, which is part of front element 307, can fit. Spring hinges are well known (see Stanley model 420766), and in effect slot holder 301 is a spring hinge where one hinge leaf is formed into the front element 307 and the other hinge leaf is formed into the L-shaped back support 319; the spring (not shown) inside the hinge barrel 303 pulls the two leaves/elements (307 and 306) together to clamp the tablet. A tab 305 extending from the middle hinge barrel 303 can be pressed to relieve the spring-induced pressure of the front and back elements on the tablet. The slot holder can also have fixed as opposed to hinged elements as in other embodiments described herein, in which case the bottom element is attached at its second edge to the front element 307 rather than to the hinge barrel 302, and the hinge barrels 302 and 303 can be eliminated. The spring provides a positive force to hold the tablet in place so that it is not so easily dislodged from the slot holder. A layer of soft material 318, such as rubber, foam or fabric, is on the inward facing surfaces of the front 307 and back elements 306 to protect the tablet.

Slot holder 301 is pivotably attached to a rigid arm 310 by vertical hinge 311 which allows the slot holder to pivot horizontally relative to the arm 310 when the holder 300 is properly oriented. The hinge 311 comprises a pin 331 attached between two prongs 333 of the arm 310 and extending through a barrel 332 attached in a vertical orientation to the back side of the back element 306. Arm 310 is pivotably attached to a mounting bracket 313 by a vertically oriented hinge barrel 312 formed in the arm which slips over a pin (not shown) attached to the bracket which allows the 310 arm to pivot horizontally relative to the bracket 313 when properly mounted into a wall, cabinet or other vertical surface so that the slot 309 of slot holder 301 is oriented upwards and the bottom edge of an inserted tablet will be horizontal. The hinge barrel 332 can be positioned near or at the middle of the back element 306 or closer to or at either end of the back element 306.

FIG. 4B shows an alternate bracket 325 for mounting holder 300 to the underside or top side of a horizontal surface which comprises a bottom plate 324 into which is mounted a rod or post 320 around which the barrel 312 can pivot. A washer 321 and nut 322 prevent the arm 310 from slipping off the post 320 if it points downwards (the post is threaded in this case). Holes in plate 324 allow mounting of the bracket 325 by screws. The arm 310 can be pivoted relative to the bracket 313 or 325, and the slot holder 301 can be pivoted relative to the arm 310 so that a user can adjust the position and angle of the tablet independently. How to mount arms pivotably to surfaces is well-known and many other types of brackets or mounts can be utilized for the tablet holder. These include brackets or clamps for attachment to non-planar surfaces, such as a pipe clamp for mounting the holder to the cylindrical post of a floor lamp.

FIG. 5A is a prospective view of a tablet computer holder 400 comprising a slot-type holder 401 pivotably attached to a mounting bracket 412 by a hinging mechanism 410. The slot-type holder 401 is formed into a channel 405 open at both ends with a planar back side or support 402 a planar bottom side 403 and planar front side or stop 404, the back side 402 slightly higher than, preferably angled somewhat away from the front side 404. The channel 405 is wide enough to comfortably fit the thin edge of a tablet computer for which it is designed and permit the tablet to lean at an angle to the vertical, supported on the back by the back side 402 and the front edge prevented from moving away from the back side by the front stop 404. One end of the back side 402 of the channel slot-type holder 401 extends horizontally further than the bottom 403 and front 404 sides, and a hinge barrel 409 is formed into this extended end 408 of the back side 402. Mounting bracket 412 has a pair of axially aligned barrels 411 formed in it which are separated by enough space for the single barrel 409 to fit between and in axial alignment with them. A pin (not shown) extends through the barrels. Most any type of hinging connection between the mounting bracket 412 and the slot-type holder 401 will work. Mounting bracket 412 is intended to be attached to a vertical surface by screws, but it can be replaced by a bracket adapted to be attached to a horizontal surface (such as that shown in FIG. 4B), such as the underside of a cabinet or a table, or to a clamping bracket or to any type of bracket that will mount securely to some solid object and hold the holder 400 in the proper orientation for use. A tablet in the holder 401 in the embodiment shown in FIG. 5A will pivot from the left to right (the left edge will pivot around the hinge); the mounting bracket can be attached to the opposite end of the channel 405 to make a holder that pivots from right to left. The channel 405 can be long enough to support the entire length of the edge of the tablet inserted into it, or somewhat less. However, if it is too short the tablet may too easily fall sideways out of the holder unless there is some mechanism holding it into the channel, such as a spring-loaded element such as that shown in FIG. 4A.

FIG. 5B shows a perspective view of a mounting bracket 430 which can replace mounting bracket 412 in holder 400, and which is adapted to clamp to a relatively thin, vertical planar element, such as the bottom of a kitchen cabinet door. The bracket 430 has a front side 433 to which a pair of properly spaced and aligned hinge barrels 434 are attached securely (such as by welding), a bottom 432 attached at its edges to edges of a front side 433 and a back side 432 and perpendicular to both, with the front and back sides spaced enough to admit the vertical planar element, such as an inch or ¾ inch for a kitchen cabinet door. In use to mount the holder 400 to a kitchen cabinet door, the front side is flush with the outside of the cabinet door, the bottom side 432 passes under the door and is preferably flush with it when mounted, and the screws 436 (only one shown) push the back side away from the door by pressing on the door (alternately they can screw into the back side of the door which leaves the front of the door unblemished by screw holes). The door facing sides of the bracket can be coated to or have layers that protect the door or other vertical planar element to which the bracket is attached. The orientation of the hinge barrels 434 can be rotated 90 degrees to allow the bracket to be mounted to the side edge of a door.

In one embodiment, the slot-type holder 401 is not attached to anything and has a plurality of holes formed in its back side 402 which can be used to mount the holder to a vertical surface like a door or a wall (such as next to a white board). In one embodiment of the slot holder 301 in FIG. 4A does not have a hinge 311 attached to its back element 306, but is mounted directly to a planar surface using an adhesive or with fasteners passing through holes in the back element 306. Either of these holders can be modified to include apparatus for charging the tablet while it is being held.

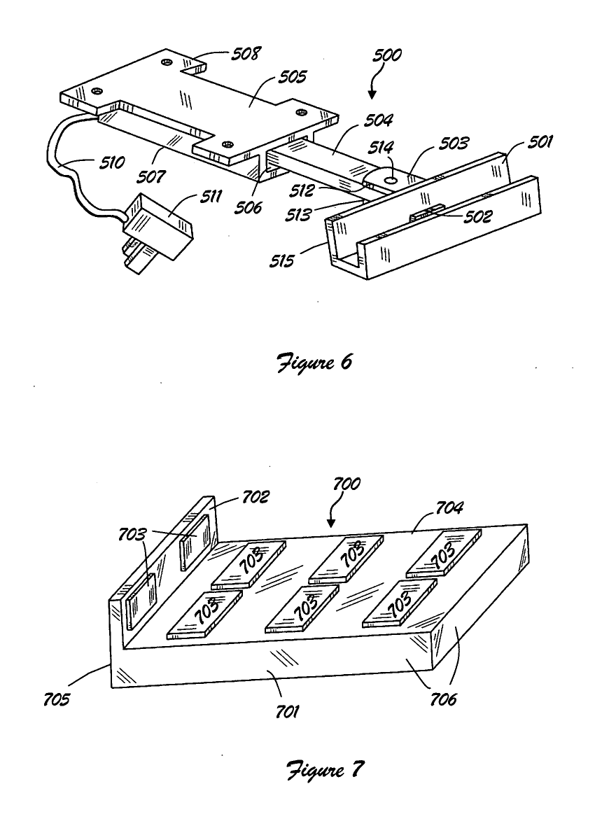

It may be advantageous that the holder be out of view or out of the way while not in use. Moreover, some homeowners may be reluctant to attach a tablet holder of the present invention to a cabinet if it involves making holes or otherwise damaging the cabinet doors exposed sides. FIG. 6 shows a perspective view of a retractable holder 500 for a tablet computer designed to be mounted to the underside of a horizontal surface, such as the underside of a cabinet, which keep any damage out of sight. The holder can be extended from beneath the surface for use or retracted back under the surface for storage.

Holder 500 comprises a slot-type holder 501 pivotably attached at a hinge 503 to a linear element 504 which is engaged with the rectangular box channel 507 of a mounting bracket 505. The hinge 503 allows the holder 501 to pivot around a vertical axis when the unit is mounted to a horizontal surface, and comprises a planar top plate 512 and a planar bottom plate 513 attached to the back side 515 of the holder 501 parallel to each other and having axially aligned holes through which a pin 514 passes. The pin 514 is attached at its ends to the two plates 512 and 513 and passes through a channel or holes in the linear element 504 which is able to pivot around the pin 514. The linear element 504 can slide into and out of the open end 506 of the box channel 507. Preferably there is a stop to prevent the linear element from sliding so far out of the channel 506 as to cause the slot-type holder to fall. Mounting bracket 505 comprises the box channel 507 and flanges 508, each having a hole for mounting the bracket 505 to the underside of a horizontal planar surface. Slot-type holder 501 comprises an electrical connector which will plug into a tablet computer to charge it when the tablet is properly inserted into the slot-type holder. An electrical wire 510 connects a plug-in transformer 511 with electrical connector 502, and runs through the inside of the box channel 507 and the linear element 504, and into the connector 502 through a hole in the slot-type holder's base (not shown). Alternate means for retracting and extending the slot-type holder from the bracket are possible, such as a scissor-type extender.

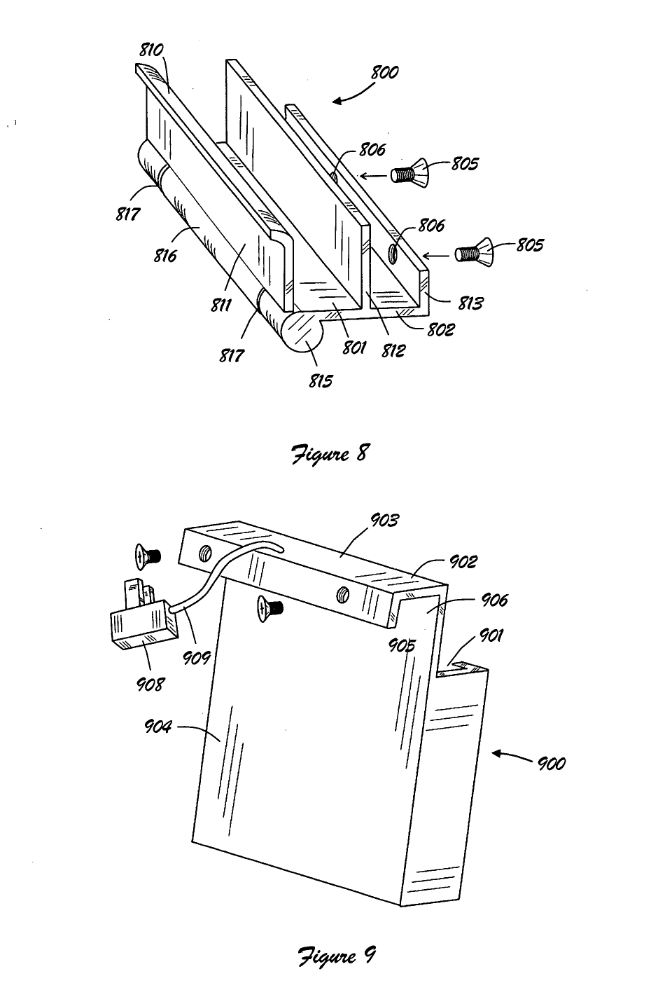

One place where users may want to mount a tablet computer is to a refrigerator door. A tablet mounted there could be used as a message board or to record grocery lists or for reference or for tracking goods in the refrigerator or for all of these uses and more. FIG. 7 shows a perspective view of a holster-type holder 700 such as that shown in FIG. 1 which is adapted for mounting to a refrigerator door, comprising an enclosure 701 with an open end 705 into which a tablet computer can be inserted. The front side (not visible) of the enclosure is mostly open with only small flanges extending perpendicularly from two or three of the enclosure's three narrow sides 206 (only two are visible) to hold in the tablet. On the back side 704 of the enclosure 701 which faces the refrigerator when in use, are arranged one or more magnets 703 of sufficient combined strength to securely attach the holder 700 to the door. If strong magnets are used, the flange 702 can be eliminated. Too many strong magnets may make it difficult to remove the holder 700 from the refrigerator door. A flange 702 adjacent to the open end 705 extends perpendicular to the back side 704 away from the opening 705. It is intended to extend over the top of the refrigerator door when in the holder 700 is attached to the refrigerator door. Magnets are also disposed on the side of the flange 702 facing the door; in one embodiment there are magnets only on the flange 702. In one embodiment, the magnets are replaced by adhesive pads. The enclosure 701 is designed to allow easy removal and insertion of the tablet, allowing the tablet computer to move enough that a user can grip it when inserting or extracting it from the holder 700. It can be designed to hold a tablet in a case or just a bare tablet. It also has a front side that does not obstruct the display of the tablet while still restraining it from falling out. If the magnets 703 are replaced by holes for screws in the flange, holder 700 can be mounted to any rectangular object. Holder 700 can be converted into a charging dock by adding, a connector in the bottom of the enclosure 701 that will mate with the charging port of the tablet and which will be connected to a transformer (if necessary) by an electrical wire. The electrical wire can be partially incorporated into the back side 704. In one embodiment, the open end 705 of the enclosure 701 is in and the flange is attached to adjacent sides of the enclosure 701 so that the tablet is slid horizontally into the enclosure 701.

FIG. 8 shows a perspective view of slot-type holder 800 which comprises a spring-loaded slot-type holder 801 (the same type as in FIG. 3) and a clamp 802 for mounting the holder 800 to the bottom of a vertical, planar object such as a cabinet door. Holder 800 has three vertical elements when mounted for use, a front 811, middle 812 and back 813 element, with front element 811 forming one leaf of a spring hinge and middle 812 and back elements part of the other leaf of the spring hinge, with the two joined by spring hinge element 815 (each leaf incorporates a barrel, with the barrel that is part of front element 811 containing the spring, although it could be the other element or another spring hinge-like design). Front element 811 incorporates a hinge-type barrel 816 housing a spring-element which presses the front element 811 against the front of the tablet, and is separated from middle element 812 by sufficient space that the tablet computer can fit between the two. The side of the middle element 812 facing away from the front element is against a front side of the door, and is separated from the opposing face of the back element 813 by sufficient distance that the door can fit into it. Screws 805 screw into threaded holes 806 in the back element and press up against the back side of the door which forces the middle element 812 to press on the front side of the door, squeezing it with enough pressure to hold the holder firmly in place (alternately, screws can just screw into the door and pull back element 813 tight against it. In one embodiment, there is a fourth vertical element between middle 812 and back 813 elements, and this fourth element presses up against the front side of the door when the screws are cranked down. There is space between middle element 812 and the fourth element. This allows the base of the tablet that is in the holder 801 to be further from the front of the door, allowing the tablet to be at an angle to the door (leaning towards it) if the middle element 812 has the appropriate angle. Front element 811 is planar adjacent to its part of the hinging element 815, but curves away from the middle element 812 at its top edge; this makes it easier to slide the tablet into the holder 801 and provides a tab that can be gripped or pressed to open the spring-loaded front element 811. A stop to keep the front element 811 from moving too close to the middle element can be incorporated into the spring-loaded hinge—this will keep the front and middle elements spaced enough to allow a tablet computer to be inserted between them, pushing the front element forward as it does. In one version of this embodiment, the spring-loading components are removed and the front element 811, middle element 812 and back element 813 are all attached along one edge to a base element. In this version, there can be an element adjacent to the middle element 812 between it and the front element 811 to force the edge of the tablet up against the front element 811 so that the tablet will lean back at its top against the door (the front element 811 can be angled slightly towards the door at its free end to encourage the tablet to lean against the door.

FIG. 9 shows holder 900 for mounting to a planar vertical object by hooking over the top of the object. The holder 900 comprises a holster-type holder or mount 901 with a mostly open front side (not shown) so that the display of the tablet can be seen, and a mounting bracket 902 attached to the back side 904 of the holster 901. A first planar element 903 of the bracket 902 is attached at a first edge perpendicularly to the top edge of the back side 904 to extend over the top of the planar vertical object to which the holder is attached and then a second planar element 905 is attached to an opposite second edge of the first element 903 perpendicular extending downwards to form a channel 906 into which the top of the vertical planar object fits. Threaded holes in the second planar element 905 allow screws to apply pressure to the back side of the vertical object, squeezing it between the back side 904 and the screws; alternately the screws can screw directly into the vertical object. This type of holder can be used with a refrigerator door, especially with one that is not ferromagnetic, and keeps the back side of the holder 901 pressed against the vertical surface. Optionally in the bottom of the holster 901 is a charging connector for mating with the charging port of a tablet computer when it is properly inserted into the holster 901, which is connected via a wire 909 to a plug-in transformer 908 (if necessary, otherwise directly to a plug).

Holster-type holders like holder 900 and holder 100 hold the tablet securely in the holder without obstructing the display. This is important because tablets often have touch-sensitive displays and the display must be accessible. The flanges on the sides need only extend far enough over the front of the tablet to prevent the tablet from falling out of the holder. In general, this type of holder is a rectangular box, generally with a solid back side and four sides perpendicular to the back side and a front side (the sides may be partial and not solid or complete), with one of the four sides open to allow insertion of the tablet into the holder, and two adjacent sides and the opposite side sized big enough to prevent the tablet from sliding out edge-wise. The two adjacent sides and opposite side also extend sufficiently over the tablet at enough points each to prevent the tablet from falling out the front side, which is mostly open; the back side is usually solid which provides structural strength and integrity. While some holders are intended primarily for storing the tablet and therefore have a solid sided enclosure (except for the side through which the tablet is inserted into the enclosure), any of the holders can have the more open enclosures of holders 900 and 100, and when the tablet is being stored, the tablet can be inserted with its display away from the mostly open side. If the holder is a charging holder, this may affect the charging connection, preventing the connector from mating with the tablet properly. Holster-type holders can be designed to accept the tablet in portrait or in landscape mode (i.e., narrow edge or wide edge first), or both.

While holster-type holders secure a tablet on three sides and in the front and back, slot-type holders secure tablets primarily by one edge. Slot-type holders comprise a front stop and a back support, two planar roughly parallel plates, connected by a bottom plate and forming a channel wide enough for a tablet computer to be inserted into it edge first. When a tablet computer is in the slot-type holder, the back side of the tablet (the side opposite the display) leans against the back support, sometimes in contact with the entire back support, sometimes only in contact with the top edge of the back support. The front stop is in contact with the front side of the tablet. The center of mass of the tablet is generally not over the channel and is in fact above a spot behind the back support, and the tablet therefore wants to pivot around the top of the back support. The front stop inhibits this pivoting by catching and pressing against the bottom front edge of the tablet. The bottom plate of the channel and the back plate are preferably sufficiently long to prevent the tablet from easily falling out to the side (i.e., being tippy side-to-side) or twisting and falling. The bottom plate prevents the tablet from slipping though. The height of the front stop must be enough to securely catch the edge of the tablet, but not so much as to interfere with viewing or accessing the display excessively. In some cases only a half-inch or even quarter-inch high front element may be sufficient. It is possible for a slot-type holder to eliminate the front stop and use a charging connector as a stop to prevent the tablet from pivoting around its point of contact with the back support (an example of this is the iPad dock from Apple). However, the principle of operation is the same; a back support for the back side of the tablet to lean against and a stop to prevent the bottom front edge from moving too far away from the back side. The back support can be perpendicular to the bottom plate or angled back away from the front stop; the angle of the back support can define the angle of the tablet or the angle can be defined by the geometry of the holder and the tablet.

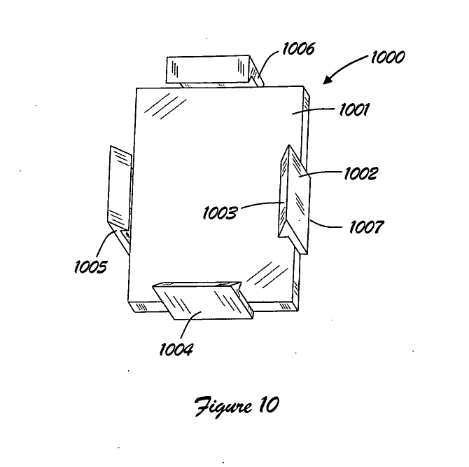

The tablet computer holding types disclosed herein can be replaced by other types of holders for tablet computers. One type of holder is one where the tablet is pressed into the holder is shown in perspective in FIG. 10. Holder 1000 comprises a rectangular planar back plate 1001 sized for a tablet computer and of sufficient strength to support the tablet, and four spring-loaded clipping mechanisms 1004, 1005, 1006 and 1007, one along each of the back plate's four edges. The spring-loaded clipping mechanisms each comprise a planar part 1002 attached at one end to one of the four edges of the back plate 1001, perpendicular to the back plate 1001 and comprised of an elastic or springy material, and a catch 1003 at the opposite end of the clipping mechanism with a sloped side facing upwards and extending in towards the opposite edge of the plate 1001. A tablet is inserted into the holder by pressing it down on the sloped upper part of the catches, which pushes them outwards enough to allow the tablet to pass; once the tablet is past, the catch snaps back and the catch's extension hooks over the tablet's front side. The catches are designed with sloped undersides so that pulling on the tablet with sufficient force will cause the spring-loaded clips to deflect backwards and out of the way. Removing the tablet may require pushing the clips back to release the tablet or simply twisting the tablet out of the holder 1000. Holder 1000 can replace any holster-type holder herein. Another type of holder is like the stretchy protective cases for smart phones; in fact many of the holders for smart phones and PDAs can be adapted for use with the tablet computers in embodiments of the present invention. Other types of holders will also be known or obvious to the skilled practitioner and can, where appropriate, be substituted for the holders in the embodiments herein. In addition, additional elements can be incorporated into the holders, such as the aforementioned induction charging station (for use with a properly equipped tablet) or speakers (with our without their own power source such as batteries) or a keyboard. The holders can also incorporate protective covers, such as a water shield.

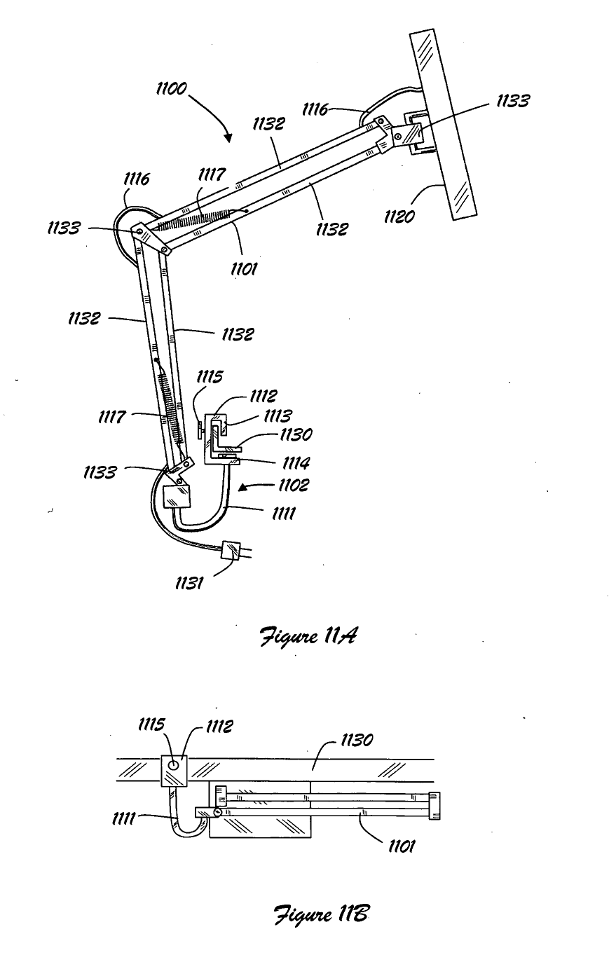

A tablet computer can be used to watch a movie in bed, but it can be tiring to hold the tablet on one's lap. Therefore, a holder for a tablet computer incorporating a swing arm may be useful. FIG. 11A shows a tablet computer holder 1100 comprising a spring balanced swing arm assembly 1101 (other types of swing arms can be used such as friction swing arms), attached at one end to a base assembly 1102 and at the other end to a holster-type tablet computer holder 1120. The swing arm is a standard spring balanced swing arm comprising arms 1132 connected by hinging mechanisms and balanced by springs 1117, with an electrical cable 1116 connecting the holder 1120 to a plug 1131 and optionally a transformer. The base assembly comprises a clamp 1113 designed to clamp to an angle iron bed frame (a segment of which is labeled 1130), with a first leg 1112 of the clamp 1113 hooking over the upward extending leg of the angle iron 1130 and a second leg 1114 of the clamp 1113 wrapping around and under the bottom leg of the angle iron 1130. One or more screws 1115 can be screwed through threaded holes in the downward extending portion of the first leg 1112 to secure the clamp better to the bed frame. Suspended downwards from the lower leg 1114 of the clamp is a J-shaped rod, the long leg of which is pivotably attached to the lower leg 1114 and the short leg of which is pivotably attached to the spring balanced swing arm assembly 701. The J-shaped rod enables the swing arm assembly 1101 to be stored under the bed frame as shown in FIG. 11B, but to extend out when in use as shown in FIG. 11A. The swing arm assembly is folded down horizontally with its two arms parallel and then the J-shaped rod is pivoted to move the swing arm under the bed frame; the tablet holder 1120 is pivoted parallel to the bed frame. Instead of the J-shaped rod, the end of the swing arm can be pivotably attached directly to the clamp 1113, for example in the portion of the first leg 1112 of the clamp 1113 that passes over the bed frame.

Swing arm or balance arms are well known and have various types of bases which allow them to be mounted to any type of surface or object. Any type of swing or balance arm and any of the bases used with them can be used in this embodiment of the invention. For example, the base can incorporate a pipe-type clamp for attaching the assembly 1100 to a floor lamp, or can incorporate the clamp that typically comes with swing arm lamps and allows for attachment of the lamp to a table. The swing arm can also have a heavy base which supports the arm and tablet.

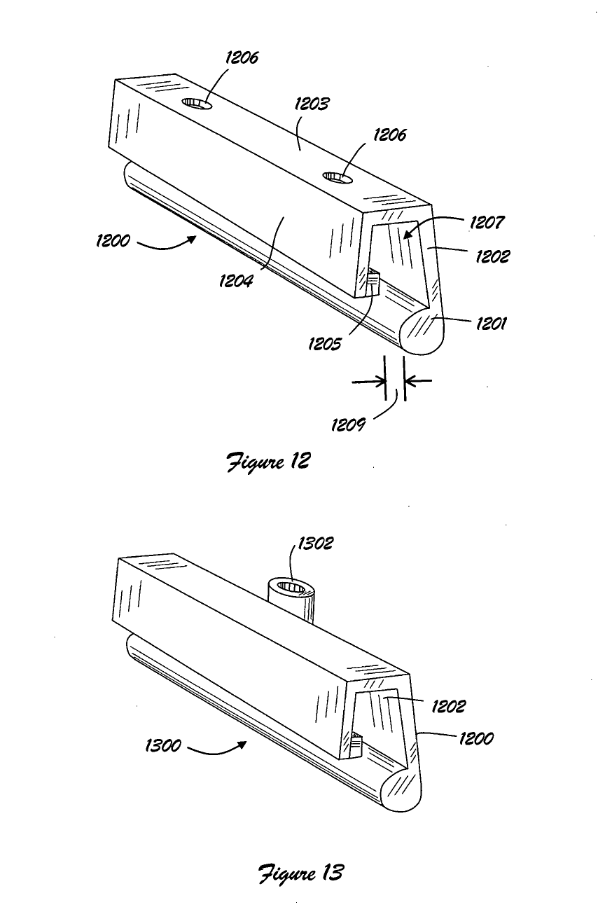

FIG. 12 is a perspective view of tablet holder 1200 which is designed for mounting under a horizontal surface, such as under a kitchen wall cabinet above the counter. The tablet is inserted into and suspended from the holder 1200. The holder 1200 is a type of slot holder that is designed so that the slot opens downwards unlike the previous slot holders whose slots or channels open upwards. The channel or slot 1207 is formed by rectangular planar back element 1202, rectangular planar top element 1203 and rectangular planar front element 1204, with one long edge of both the back element 1202 and the front element 1204 attached to opposite long edges of the top element 1203. Attached to the second long edge of the back element 1202 is a cylindrical element 1201. It is attached so that it is flush with the plane of the back element 1202 and projects inwards from the back element 1202 towards the front element 1204. On inwardly facing side of the front element 1204 (the side closest to the back element 1202) is a layer of material 1205 that is has a high coefficient of friction when pressed against the front of a tablet (typically a glass or plastic). The horizontal distance 1209 between the vertical planes intersecting the closest points of the material 1205 and the cylindrical element 1201 is less than the thickness of the tablet computer for which the holder 1200 is designed, but the gap between the material 1205 and the cylindrical element 1201 is bigger than the thickness of the tablet computer. As a result, the tablet computer can slip between the two elements 1201 and 1205, but cannot be pivoted into a vertical position (if it could, the tablet would simply slip out of the slot 1207. In the top element are two holes for mounting the holder 1200 to a planar surface. This holder can be looked at as a roughly rectangular channel fully closed on two adjacent sides (1202 and 1203) with a partial third side (1204) and a partial fourth side (1201) projecting one each from the other two sides towards a virtual intersection (if the third and fourth sides are extended they would intersect and close the channel). The distance between the free edges of the third side 1204 and the fourth side 1201 is greater than the thickness of the tablet computer to allow it to be inserted partially into the channel, but the distance between the outer edge of the fourth side 1201 and the virtual intersection is less than the thickness of the tablet computer. This latter restriction forces the tablet to remain at an angle to the vertical since there is not enough distance between the outermost edge of the fourth side 1201 and the innermost points of the third side 1204. In its simplest form, the channel 1207 can be rectangular, with the cylindrical element 1201 replaced by a planar rectangular side perpendicular to the back element 1202 and the front element 1204 extending downwards perpendicular to the top element 1203, but leaving a gap into which the tablet computer can be inserted.

When a tablet computer is inserted up into the slot, the rod-like or cylindrical element 1201 forces the tablet to go into the slot 1207 at an angle, ensuring that the center of mass is not directly below the upper edge of the tablet (the edge being inserted). The force on the center of mass causes the tablet to press up against and then start to pivot around the cylindrical element, forcing the front of the tablet up against the high friction material 1205. The force of the cylindrical element 1201 on the back of the tablet and of the high friction material 1205 on the front of the tablet combined with the friction of the material 1205, act to firmly grip the edge of the tablet and hold it at an upwardly facing angle to the vertical. To improve the grip a high friction layer can be added to or formed in the surface of the cylindrical element 1205. The slot 1207 is designed to be big enough that a tablet computer (the specific models for which it is designed) can be easily slipped into it if they are at a certain angle that is further from the vertical than the angle at which the tablet will hang when secure in the holder. To use, a person simply slips the tablet up into the slot 1207 at that angle, then gently presses the back of the tablet against the cylindrical element 1201 and pivots the tablet around it until the front of the tablet presses up against the friction material 1205; the tablet can then be released. To remove the tablet from the holder 1200, the person simply reverses those steps. A charging connector can be incorporated into the holder 1200 that will plug into the charging port of the tablet computer that is inserted. In order to allow the tablet to pivot against the friction pad 1205 the connector should be mounted so that it can move towards and away from the back element 1202.

The holder 1200 can be mounted to a vertical surface and hold a tablet provided it is mounted a sufficient angle to the vertical that the tablet presses sufficiently hard against the cylindrical element 1201 and the friction pad 1205 to grip the tablet securely. The holder 301 in FIG. 4A can also be mounted to a vertical surface (for instance by attaching the back element 306 to the vertical surface with fasteners or an adhesive) and hold a tablet securely by its vertical edge, provided the spring is sufficiently strong and the antifriction layers on the front 307 and back 306 elements (layer 318 is shown) provide sufficient friction to prevent the tablet from slipping.

Some tablet computers may have features on their front or back side that can be used by a holder such as holder 1200 to create a more secure grip. For example, the front side of the tablet may have a linear groove into which the element 1205 can fit, particularly if it is specifically tailored to do so (the friction material 1205 may be replaced by a set of bosses or a rib that fits into the groove in the front of the tablet. Likewise, there may be a shallow, cylindrical groove matching the contour of the element 1201 and into which the element 1201 can fit. Such interactions between the tablet computer design and the holder design will enhance ability of the holder to hold the computer, helping prevent it from slipping out inadvertently.

The tablet computer holder 1300 shown in perspective in FIG. 13 comprises the tablet holder 1200 without the mounting holes 1206, but with a cylindrical hinge barrel 1302 (could simply be a hole in a bracket) attached to the back 1202 of the holder 1200, with its cylindrical hole perpendicular to long dimension of the back 1202 so that it is vertically aligned in use. The mounting bracket 325 shown in FIG. 4B can used to mount the holder 1300 to the underside of a horizontal surface such as a kitchen wall cabinet (threading the rod 320 through the hinge barrel 1302 with the threaded end down, then placing the washer 321 and nut 322 on the rod 320 to prevent the holder 1300 from slipping off). In the embodiment shown in FIG. 13, the hinge barrel 1302 is positioned in the middle of the length of the back 1202, allowing the holder 1300 to pivot around its center in the horizontal plane, which enables a user to change the direction in which the computer display points. In another embodiment, the hinge barrel 1302 is attached to holder 1300 at one end so that the holder pivots from its end.

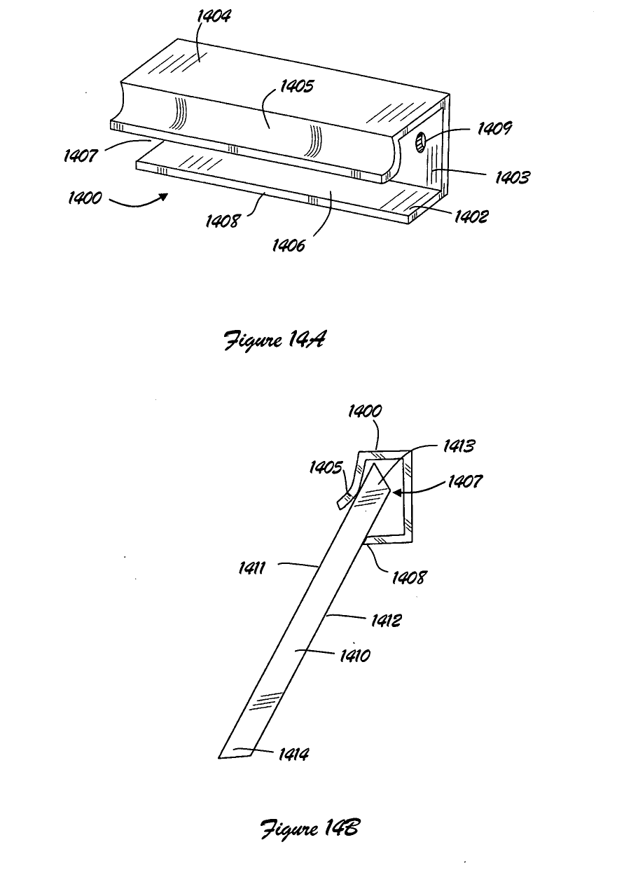

FIG. 14A shows another tablet computer holder 1400 which can be mounted to a vertical planar surface, such as the wall of a restroom stall (the holder 1400 can be adapted to mount under a horizontal planar surface by adding holes in the top side 1404, and the holder 1200 can be adapted for mounting to a vertical planar surface by moving the holes 1206 to the back side 1202). It comprises a rectangular planar back side 1403 having a long dimension which will be horizontal when the holder is in use, with a rectangular planar bottom element 1402 extending perpendicularly from one long edge of the back 1403 and a rectangular planar top element or side 1404 extending roughly perpendicularly from the other long edge of the back 1403, both extending in the same direction away from the back. To the other long edge of the top element 1402 is attached a semi-cylindrical element 1405 which extends towards the bottom element 1402, starting roughly perpendicular to the top element 1402 and then curving between about 30 and 90 degrees away from the back side 1403. There is a space or slot 1407 between the semi-cylindrical element 1405 and the bottom element 1402 into which a tablet computer can be slid. Two or more holes 1409 are formed in the back side 1403 to allow mounting to a wall or other vertical surface.

FIG. 14B is a side view showing how a tablet computer is held by the holder 1400. The top edge 1413 of the tablet computer 1410 is inserted into the slot 1407, the back side 1412 of the computer 1400 is placed against the outer edge 1408 (the long edge opposite the one attached to the back side 1403), and the computer 1410 is pivoted around that edge 1408 until the front side 1411 of the computer 1410 is against the inner side (the side facing towards the back side 1403 and bottom element 1402) of the semi-cylindrical element 1405. The force of the tablet computer 1410 trying to pivot its center of mass (typically about midway between the top edge 1413 and the bottom edge 1414 of the tablet 1410) will hold it in place. The ability of the edge 1408 to grip (not slip on) the back side 1412 of the tablet and of the inner surface of the semi-cylindrical element to prevent the front side 1411 of the tablet from slipping past it can both be increased, such as by adding a layer of material with a high coefficient of friction with the surface of tablet computers or modifying their surfaces to create more friction (e.g., roughening or adding grooves). Both the holder 1200 and the holder 1400 can be made from extruded plastic or metal (such as aluminum) since the cross-section of each is consistent along its length.

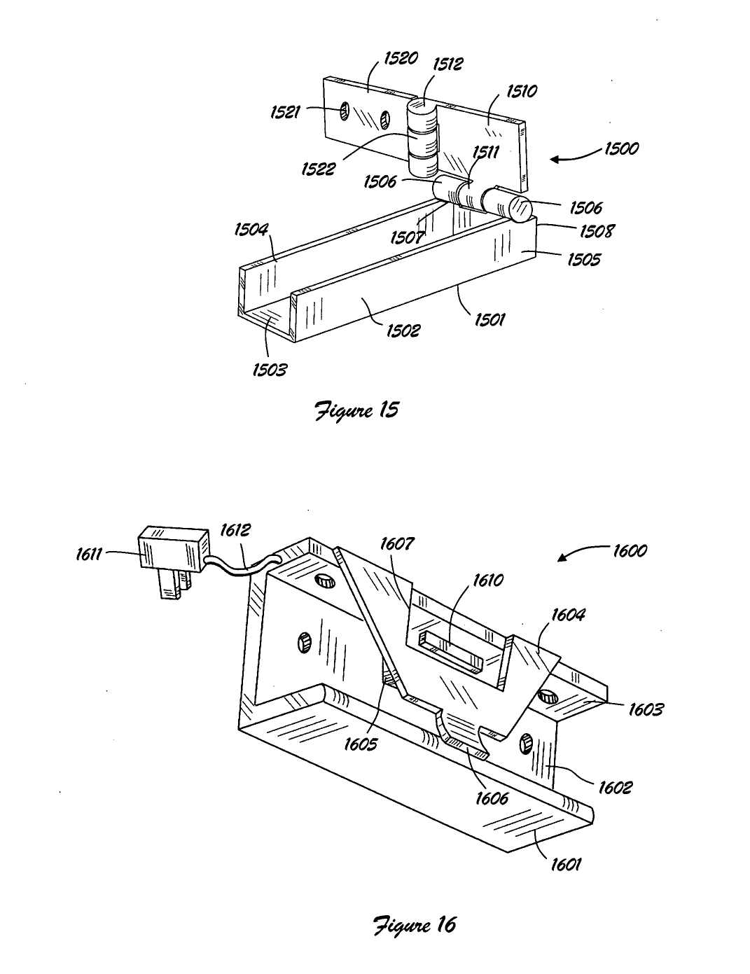

The tablet computer holder 1500 shown in perspective in FIG. 15 is designed to be mounted on a vertical surface, such as a wall or the side of a cabinet. A slot-type tablet holder 1501 forms one ‘leaf’ of a spring hinge 1507. The spring hinge 1507 comprises two cylindrical hinge barrel elements 1506 which are attached to the holder 1501 at its closed end 1508, and a cylindrical center barrel element 1511 between and axially aligned with the two cylindrical barrels 1506 which is attached to a first rectangular planar hinge leaf 1510 along one edge (or formed by two prong extensions from its edge). A hinge pin (not shown) passes through. The hinge unit 1507 is a spring hinge which, absent the weight of a tablet computer, will pull the slot holder 1501 up to the first leaf 1510.

An adjacent edge of the first leaf 1510 is formed into the two end barrel elements of a hinge 1512 with a space in between them, into which fits a center barrel 1522 which is formed from a prong extending from one edge of a second hinge leaf 1520. The hinge 1512 connecting the first leaf 1510 and the second leaf 1520 is orthogonal to the spring hinge 1507. While the second leaf 1520 is shown to the side and in the same plane as the first leaf 1510, it is intended to fold behind the first leaf 1510. The second hinge leaf 1520 has two holes 1521 by which it can be mounted to a horizontal surface using fasteners. When properly mounted, the first hinge 1507 will be horizontal and the second hinge 1512 will be vertical. The holder 1501 will be pressing against the wall (the spring [not shown] in the spring hinge 1507 pulling it up), with the slot vertically aligned. The spring in the hinge 1507 is of sufficient strength to maintain the holder 1501 in a vertical position against the wall when not in use, but of insufficient strength to lift a tablet computer that is put into it after the holder 1501 has been pulled into a horizontal position. To keep the holder 1501 horizontal when pulled down and prevent it from folding too far down, the closed end 1508 of the holder 1501 extends beyond the hinge 1507 sufficiently so that it is up against the vertical surface when the holder is horizontal for use. The second hinge 1512 allows the angle of the holder 1501 relative to the vertical surface to be changed in the horizontal plane. Alternative means of achieving a fold-down holder that pivots can be used.

In an alternate embodiment, the second hinge 1512 and the second leaf 1520 are eliminated and holes are formed in the first leaf 1510 for mounting to a vertical surface. In a variation of this embodiment, the first leaf 1510 is replace with the mounting bracket 430 shown in FIG. 5B, except with the hinge barrels 434 rotated ninety degrees.

FIG. 16 is a perspective view of a holder 1600 from which a tablet computer can be suspended. It comprises a rectangular planar back element 1602 which is attached roughly orthogonal along a first edge to a support element 1601 against which the back of the tablet computer will rest, a rectangular planar top element 1603 which is attached roughly orthogonally to a second and opposing edge of element 1602, such that both the top element 1603 and the support element 1601 are roughly parallel and project away from the same side of the back element 1602 (they are facing). From the side of the top element 1603 facing the support element 1601 projects an electrical connector 1610 (for charging a tablet computer or connecting it to other devices) of the appropriate dimensions, and positioned appropriately on the top element 1603, to be able to mate with the complementary port of the tablet computer for which it is designed. The electrical connector 1610 may be at an angle or attached to a somewhat flexible substrate, and is attached electrically via an electrical cable 1602 (partially embedded in the top element 1603 and therefore not wholly visible) to a second connector 1611 which may be incorporate a transformer and/or prongs for plugging into an electrical outlet.

Attached to the edge of the top element opposite the edge attached to the back element 1602 is a clamping element 1604 which projects at a slight angle away from the back element 1602. The clamping element has an opening 1607 through which the electrical connector 1610 can be observed; this makes it easier to make sure it is inserted properly into the tablet's port. On the edge opposite the edge at which the clamping element 1604 is attached to the top element 1603 is a tab 1606 which curves slightly up and away from the back side 1602. On the side of the clamping element 1604 facing the back side 1602 is a strip of soft, high friction material 1605 (such as foam rubber) which will press against the front of the tablet computer between the points on its front side opposite the points on the back side that the tablet computer will rest against and the top edge of the tablet computer which will be up against or close to the top element 1603. The clamping element 1604 is made of a rigid, but springy material that can be bent away from the support element 1601 so that the computer can be inserted into the holder 1600 but which will then try to return to its original position, applying a force to the front of the tablet computer.

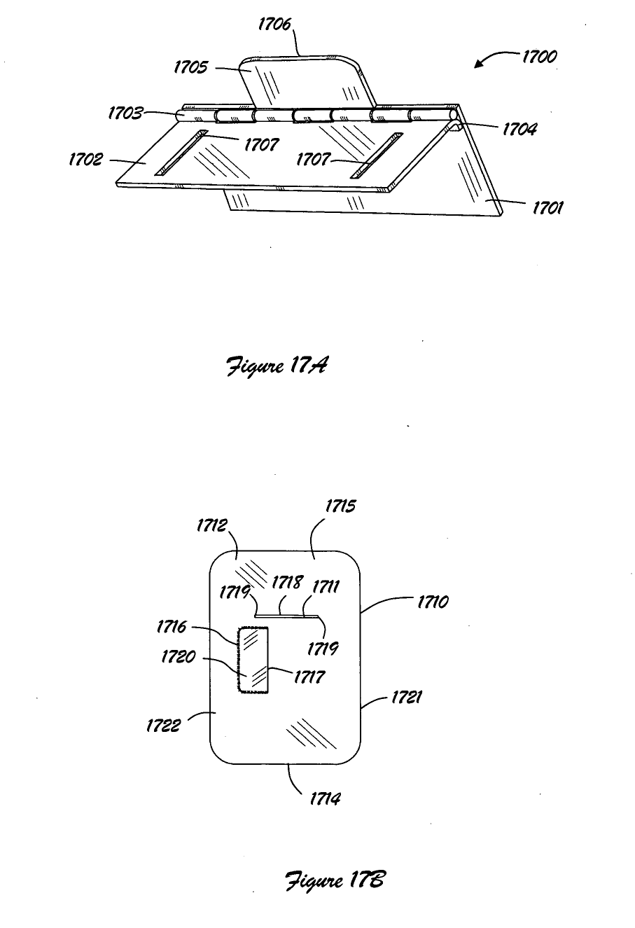

FIG. 17A is a perspective view of a holder 1700 for tablet computers designed to work in conjunction with a specially adapted tablet computer case or housing. The holder comprises a rectangular planar mounting plate 1702 having a flange 1704 along one edge. Attached at the edge of the mounting plate 1702 adjacent to the flange 1704 is a hinge element 1703. Also attached to the hinge, roughly orthogonal to the mounting plate 1702 is a planar rectangular support plate 1701. Attached to (or extending from) and in the same plane as the support plate 1701 is a tab 1705. The tab 1705 has straight sides extending away from the support plate 1701, and a slightly curved and rounded edge1706 opposite the edge where the tab 1705 and the support plate 1701 are joined. The tab 1705 is centered along the edge of the support plate 1701, and is less wide, although it can be as wide or wider. The hinging element 1703 can be a mechanical hinge or other mechanism that allows the support plate 1701 and the mounting plate 1702 to change their angle relative to one another with the hinging element 1703 at the vertex. The flange 1704 acts as a stop to prevent the support plate 1701 and the mounting plate 1702 from forming too small an angle (the smallest angle allowed may be 90 degrees or perhaps somewhat less. The hinging element 1703 is sticky, in that it takes effort to change the angle between the support and mounting plates, and once a person does change the angle by moving the support plate 1701, the holder will remain in that position, even when supporting a tablet computer. There are two slots 1707 in the mounting plate 1702 aligned perpendicular to the hinging element 1703 which are used to mount the holder to a horizontal surface; the slots 1707 are intended to allow a person to adjust how far the support plate 1701 is out from the edge of the horizontal surface to which the holder is attached. The mounting plate can be adapted to attach to the bottom of a door, such as holder 800, a vertical surface or to a balance arm (such as in FIG. 11A), or to incorporate any of the other mounting mechanisms described herein which are appropriate.

FIG. 17B is a plan view of the back of a case 1710 for a tablet computer. Tablet computers are often placed into these cases for protection or ease of handling. The case 1710 may be formed of a hard material, such as metal or plastic, or a softer material, such as fabric or plastic. The front side of the case, not shown, is in a form which allows a user interact with the tablet's display and controls yet still snugly hold the tablet. Formed into the back side 1712 of the case 1710 is a slot 1711 which is intended to support the tablet computer in portrait orientation. It is perpendicular to the long edges 1721, 1722 of the tablet, centered between them, and situated about one-third or one-quarter of the way between the top edge 1715 and bottom edge 1714 of the case. To use the holder 1710, the tab 1705 is slipped into the slot 1711 with the tab 1705 pointing towards the top edge 1715 (the tab 1705 can be thought of as the insertion element, for inserting into a slot or pocket or recess). When the tab 1705 is slipped into the slot 1711, it is slipped between the tablet computer back and the case 1710. The slot 1711 is preferably slightly wider than the tab 1705. When in use with holder 1700, the case 1710 (and the tablet computer it is holding) is supported by the tab 1705 through its slot 1711, and the support plate 1701 supports the lower part of the tablet by pressing against the outside of the case 1710. If the case is made from a rigid material, a recess may be formed above the slot (toward the top edge 1715) between the case and the tablet to provide a space or pocket into which the tab can be inserted. This will likely create a bulge in the case. If the case is a softer material, the upper edge 1718 and corners 1719 of the slot 1711 may be reinforced.

The case 1710 also comprises a second means of attaching to the holder 1700, a pocket 1716 attached to the outside of the case 1710. The pocket comprises a roughly rectangular piece of material 1720 (the same or different from the adjacent part of the case) which is attached to the case 1710 along three edges (the edges parallel to the top edge 1715, and the edge closest to the left side 1722 of the case {in the current orientation; this is the side that will be up when the pocket 1720 is used with the holder 1700}), by means such as sewing, adhesion or welding. The fourth side 1717 is the opening of the pocket 1720 (the pocket is similar to the back pockets found on many jeans, simply a piece of material attached over another piece of material), into which the tab 1705 can be slipped to support the case 1710 and the tablet in it. The opening 1717 of the pocket is centered between the two short edges 1715, 1714 or the case, parallel to the long sides 1721, 1722, and situated approximately one-third or one-quarter of the way between the left long edge 1722 and the right long edge 1721. To use with the holder 1700, a person orients the case 1710 vertically in a landscape orientation with the pocket 1720 facing downwards, and then slips the tab 1705 into the pocket 1720. The support plate 1701 will rest against the outside of the case below the opening 1717 of the pocket 1720 (below is towards the right edge 1721 in the present embodiment as show). If the case is made of a rigid material, the pocket can be in the form of a raised section of the case with a recess behind it that creates enough space for the tab 1705 to fit between the case and the tablet computer. Note that the slot 1711 and the opening 1717 are perpendicular to one another to allow the case to be attached to the holder 1700 in either a portrait or landscape orientation.

Different embodiments can have two slots or two pockets oriented perpendicular to each other. The slot may be modified to have a pocket extending from it behind the case (similar to the front pockets of jeans which have a slot and then a fabric pocket formed behind it). Almost any type tablet computer case can be modified cheaply and easily to incorporate either a slot, a recess or a pocket to support the tablet using a holder like the holder 1700, and such modification will not affect the functionality or ease of use of the case. A case may have only one slot or pocket, or it can have two or more.

The dimensions of the holders are appropriate to the tablet computer or computers for which they are designed. For example, if a tablet computer is one-half inch thick, a slot holder for that computer will have a slot at least one-half inch wide, but preferably somewhat wider, such as ⅝, ¾, ⅞, 1 inch and even more, depending upon the angle at which it is desirable for the tablet to lean. Holster-type holders preferably have only a limited amount of clearance for the computer, such as an enclosure that is 1/16, ⅛ or ¼ inch bigger than the corresponding dimensions wherever the enclosure encloses the tablet.

The back element of slot-type holders against which the tablet computer will lean must be high enough to keep the tablet from being able to pivot out of the slot, and may be ½, ⅝, ¾, ⅞, 1, 1.125, 1.25, 1.5 or mover high. It must be wide enough to provide a relatively stable support for the tablet computer, such as 1, 2, 3, 4, 5 or more inches up to the longest dimension of the tablet computer. The front stop or element of a slot-type holder must be high enough to securely catch the front edge of the tablet computer and prevent it from easily slipping up and then pivoting over the back element. This may be as low as ¼ inch up to about ¾ inch; if it is much higher it will interfere with viewing of the display and access to the buttons/controls for the tablet. If the front element is wide, the back element can be narrower, and vice versa, without sacrificing stability. The plug for charging and connecting the tablet to other devices can replace the front element.

Holders from which tablet computers hang, such as those shown in FIGS. 13 and 14A, have similar dimensions to the slot-type holders. The element against which the back of the tablet computer pushes (e.g. 1201 and 1402) is preferably pressing against a portion of the back side of the tablet computer at least about 1 inch from its top edge (this can be less) so that the tablet can slip down slightly without falling out of the holder. The element that pushes against the front side of the tablet computer (i.e., the display or its frame) (e.g., 1205 and 1405) must be in contact with the front side above the point(s) of contact on the back side (in other words, closer to the top edge of the tablet computer), such as ⅜, ½, ⅝, ¾, ⅞ or 1 inch in from the top edge, provided the point of contact is preferably at least about ½ inch further in from the top edge. If indentations or bosses on the front and back of the tablet engage with complementary elements of the holder, these dimensions can change. The element pressing against the back of the computer can be any width, but is preferably relatively wide (such as 3 or more inches, or, if measured relative to the tablet, more than half of its horizontal dimension when hanging from the holder) so that it presses across a relatively large portion of the back of the tablet computer and helps prevent it from twisting side to side (this may cause it to fall out). The element pressing against the front of the tablet can be less wide than the element pressing against the back, especially if the latter is wide (e.g., close to or as wide as the tablet computer) (the reverse is also true). To achieve the most stable hold on the tablet and help ensure that the tablet will not twist in the holder when a user interacts with its touch screen or controls, both of the elements pressing against the front and back of the tablet computer are preferably at least one-half the width of the tablet computer (i.e., are in contact along a line at least one-half as long as the computer's dimension along that same line), and preferably as wide as the smaller of the rectangular tablet computers large dimensions.

The various holders for tablet computers described herein can be designed to hold tablet computers with or without cases or both. If the holder is to operate with a tablet computer in a case, the dimensions of the holder may need to be adapted.

The term holder is used in two ways in this disclosure. It is sometimes used to refer to the entire device that operates to hold the tablet computer. At other times it is used to refer to that part of the overall device (or holder) that actually binds, restrains, supports or otherwise holds the tablet computer itself. Sometimes the term dock and mount is used instead of holder. The numbering of parts should make clear which meaning of the term is intended.

The inventions herein are not limited in their application to the details of construction and the arrangement of components set forth in the preceding description or illustrated in the drawings.

The inventions are capable of embodiments and of being practiced or of being carried out in various ways beyond those exemplarily presented herein.

Having now described some illustrative embodiments of the invention, it should be apparent to those skilled in the art that the foregoing is merely illustrative and not limiting, having been presented by way of example only. Numerous modifications and other embodiments are within the scope of one of ordinary skill in the art and are contemplated as falling within the scope of the invention. In particular, although many of the examples presented herein involve specific combinations of method acts or system elements, it should be understood that those acts and those elements may be combined in other ways to accomplish the same objectives.

Further, acts, elements, and features discussed only in connection with one embodiment are not intended to be excluded from a similar role in other embodiments.

It is to be appreciated that various alterations, modifications, and improvements can readily occur to those skilled in the art and that such alterations, modifications, and improvements are intended to be part of the disclosure and within the spirit and scope of the invention.

Moreover, it should also be appreciated that the invention is directed to each feature, system, subsystem, or technique described herein and any combination of two or more features, systems, subsystems, or techniques described herein and any combination of two or more features, systems, subsystems, and/or methods, if such features, systems, subsystems, and techniques are not mutually inconsistent, is considered to be within the scope of the invention as embodied in the claims.

Use of ordinal terms such as “first,” “second,” “third,” and the like in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

Those skilled in the art should appreciate that the parameters and configurations described herein are exemplary and that actual parameters and/or configurations will depend on the specific application in which the systems and techniques of the invention are used.

Those skilled in the art should also recognize or be able to ascertain, using no more than routine experimentation, equivalents to the specific embodiments of the invention. It is therefore to be understood that the embodiments described herein are presented by way of example only and that, within the scope of the appended claims and equivalents thereto; the invention may be practiced otherwise than as specifically described.

What is claimed:

1. A holder for a tablet computer comprising a holder and a mounting bracket adapted for attaching to an object.

2. The holder for a tablet computer wherein the object is a bed frame.

3. The holder for a tablet computer of claim 2 wherein the bed frame comprises angle iron and the bracket comprises a flange forming a slot into which the angle iron can be deposed.

4. The holder for a tablet computer of claim 2 further comprising a charging dock for the tablet computer.

5. The holder for a tablet computer of claim 2 wherein the bracket is adapted to hold the tablet computer in a vertical orientation.

6. The holder for a tablet computer of claim 2 wherein the bracket is adapted to hold the tablet computer in a horizontal orientation.

7. The holder for a tablet computer of claim 1 wherein the object is a horizontal surface.

8. The holder for a tablet computer of claim 1 wherein the object is a vertical surface.

9. The holder for a tablet computer of claim 1 wherein the object is the bottom edge of a vertically oriented planar object.

10. The holder for a tablet computer of claim 9 wherein the vertically oriented planar object is a door.

11. The holder for a tablet computer of claim 1 wherein the mounting bracket is adapted for attaching to the top edge of a vertically oriented planar object.

12. The holder for a tablet computer of claim 11 wherein the vertically oriented planar object is a door.

13. The holder for a tablet computer of claim 1 wherein the holder is pivotably attached to the mounting bracket.

14. The holder for a tablet computer of claim 1 further comprising an arm pivotably attached to the holder at a first end and pivotably attached to the mounting bracket at a second end.

15. The holder for a tablet computer of claim 1 further comprising an elongate element attached to the holder at a first end with its second end disposed within a housing attached to the mounting bracket.

16. The holder for a tablet computer of claim 1 wherein the holder is a slot-type holder.

17. The holder for a tablet computer of claim 16 wherein the slot-type holder comprises a spring mechanism adapted to partially close the slot.

18. The holder for a tablet computer of claim 1 further comprising a balanced swing arm attached to the holder at a first end and pivotably attached to the mounting bracket at a second end.

19. The holder for a tablet computer of claim 1 wherein the holder comprises a roughly rectangular channel having a first and a second roughly rectangular sides attached one to the other along a first edge at a roughly perpendicular angle, with a roughly rectangular third side extending from the second side roughly parallel to the first side and a roughly rectangular fourth side extending from the first side roughly parallel to the second side, wherein the third and fourth sides extend away from the second and first sides respectively towards a virtual line of intersection, wherein the dimensions of the third side and the fourth perpendicular to the edge at which the first and second sides are attached are less than the equivalent dimensions of the first and second sides respectively, and wherein the gap formed between the free edges of the third and fourth sides is larger than the thickness of the tablet computer and the distance between the formed by a second element and the virtual line of intersection is less than the thickness of the tablet computer.

20. The holder for a tablet computer of claim 19 further comprising a mounting bracket pivotably attached to the holder.

21. The holder for a tablet computer of claim 20 further comprising a charging dock.
